(19) United States
(12) Patent Application Publication
(10) Pub. No.: US 2015/0055731 A1
(43) Pub. Date: Feb. 26, 2015

(54) Digital Transmitter With Sample Rate Digital Predistortion

(71) Applicant: Broadcom Corporation, Irvine, CA (US)

(72) Inventors: David HARRIS, Upland, CA (US); David Garrett, Tustin, CA (US)

(73) Assignee: Broadcom Corporation, Irvine, CA (US)

(21) Appl. No.: 14/106,251

(22) Filed: Dec. 13, 2013

Related U.S. Application Data
(60) Provisional application No. 61/867,886, filed on Aug. 20, 2013.

(51) Int. Cl. H04B 1/04; H03F 1/32

(52) U.S. Cl. CPC H04B 1/0475; H03F 1/3241; H03F 2201/3233
USPC 375/296

(57) ABSTRACT

A digital transmitter with sample rate digital predistortion is disclosed. The transmitter includes a digital radio frequency (RF) signal generator configured to receive a baseband digital signal and transform the baseband digital signal to a digital RF signal. The digital transmitter further includes a sample rate predistorter configured to predistort the digital RF signal so as to compensate for distortion associated with the transmitter that is generated subsequent to an output of the sample rate predistorter, and resulting in a digital predistorted RF signal. The digital transmitter further includes a digital to analog converter configured to convert the digital predistorted RF signal to analog, resulting in an analog predistorted RF signal.

### CROSS REFERENCE TO RELATED APPLICATIONS

The present application claims priority to U.S. Provisional Patent Application No. 61/867,886, filed on Aug. 20, 2013, which is hereby incorporated by reference in its entirety.

### BACKGROUND

1. Field

The present disclosure relates generally to a transmitter configured to predistort digital radio frequency (RF) signal so as to compensate for distortion associated with the transmitter.

2. Background Art

Signal distortion is an unwanted phenomenon that occurs in many communications and signal processing devices. Such signal distortion is common in transmitters due to, for example, the gain function of a power amplifier included in the transmitter. To compensate for the distortion produced by, for example, the power amplifiers, a conventional transmitter may employ predistortion mechanisms that measure the envelope of baseband signals to be transmitted and apply the predistortion on the baseband signals. This method is effective in removing the peak compression of the RF signal, but over-compensates the rest of the RF signal.

### BRIEF DESCRIPTION OF THE DRAWINGS/FIGURES

The accompanying drawings, which are incorporated herein and form part of the specification, illustrate the present disclosure and together with the description, further serve to explain the principles of the disclosure and to enable a person skilled in the relevant art(s) to make and use the disclosure.

FIG. 1 illustrates a system, in accordance with an embodiment of the present disclosure.

FIG. 2 illustrates a conventional transmitter where the predistortion is applied on a baseband signal based on the envelope of the signal.

FIG. 3 illustrates distortion and predistortion gains.

FIG. 4A illustrates an ideal transmit signal oscillating at a carrier frequency within an envelope.

FIG. 4B illustrates distorted and corrected output signals for a conventional transmitter.

FIG. 4C illustrates the impact of distortion and envelope predistortion in frequency domain for a conventional transmitter.

FIG. 5A illustrates a digital transmitter with sample rate digital predistortion, in accordance with an embodiment of the present disclosure.

FIG. 5B illustrates a transmit signal within a digital transmitter with sample rate digital predistortion, in accordance with an embodiment of the present disclosure.

FIG. 6 illustrates an implementation of predistort module, in accordance with an embodiment of the present disclosure.

FIG. 7A illustrates sample rate predistortion in time domain, in accordance with an embodiment of the present disclosure.

FIG. 7B illustrates sample rate predistortion in frequency domain, in accordance with an embodiment of the present disclosure.

FIG. 8 is a flowchart illustrating a method, in accordance with an embodiment of the present disclosure.

FIG. 9 illustrates a computer system that can be utilized to implement one or more embodiments of the present disclosure.

The present disclosure will now be described with reference to the accompanying drawings. In the drawings, generally, like reference numbers indicate identical or functionally similar elements. Additionally, generally, the left-most digit(s) of a reference number identifies the drawing in which the reference number first appears.

### DETAILED DESCRIPTION

### Overview

Apparatuses and methods are provided to efficiently and more effectively predistort signals before being transmitted. According to a first embodiment of the disclosure, a transmitter is provided that includes a digital RF signal generator configured to receive a baseband digital signal and transform the baseband digital signal to a digital RE signal. The transmitter further includes a sample rate predistorter configured to predistort the digital RE signal so as to compensate for distortion associated with the transmitter that is generated subsequent to an output of the sample rate predistorter, and resulting in a digital predistorted RE signal. The transmitter further includes a digital to analog converter (DAC) configured to convert the digital predistorted RF signal to analog, resulting in an analog predistorted RF signal. The analog signal is already at RF frequencies and therefore can be directly connected to a power amplifier (PA), or pre-amplifier filtering.

According to another embodiment of the disclosure, there is provided a method for receiving a baseband digital signal and transforming the baseband digital signal to a digital RE signal. The method further includes predistorting the digital RE signal so as to compensate for distortion that is generated subsequent to the predistorting, and resulting in a digital predistorted RE signal. The method also includes converting the digital predistorted RE signal to an analog predistorted RF signal.

### Detailed Discussion

The following Detailed Description of the present disclosure refers to the accompanying drawings that illustrate exemplary embodiments consistent with this disclosure. The exemplary embodiments will so fully reveal the general nature of the disclosure that others can, by applying knowledge of those skilled in relevant art(s), readily modify and/or adapt for various applications such exemplary embodiments, without undue experimentation, without departing from the spirit and scope of the disclosure. Therefore, such adaptations and modifications are intended to be within the meaning and plurality of equivalents of the exemplary embodiments based upon the teaching and guidance presented herein. It is to be understood that the phraseology or terminology herein is for the purpose of description and not of limitation, such that the terminology or phraseology of the present specification is to be interpreted by those skilled in relevant art(s) in light of the teachings herein. Therefore, the detailed description is not meant to limit the present disclosure.

The embodiment(s) described, and references in the specification to “one embodiment”, “an embodiment”, “an example embodiment”, etc., indicate that the embodiment(s) described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is understood that it is within the knowledge of one skilled in the art to effect such feature, structure, or characteristic in connection with other embodiments whether or not explicitly described.

Embodiments of the disclosure may be implemented in hardware, firmware, software, or any combination thereof. Embodiments of the disclosure may also be implemented as instructions stored on a machine-readable medium, which may be read and executed by one or more processors. A machine-readable medium may include any mechanism for storing or transmitting information in a fount readable by a machine (e.g., a computing device). For example, a machine-readable medium may include read only memory (ROM); random access memory (RAM); magnetic disk storage media; optical storage media; flash memory devices. Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc.

For purposes of this discussion, the term “module” and the like, shall be understood to include at least one of software, firmware, and hardware (such as one or more circuits, microchips, processors, or devices, or any combination thereof), and any combination thereof. In addition, it will be understood that each module can include one, or more than one, component within an actual device, and each component that forms a part of the described module can function either cooperatively or independently of any other component forming a part of the module. Conversely, multiple modules described herein can represent a single component within an actual device. Further, components within a module can be in a single device or distributed among multiple devices in a wired or wireless manner.

Terms like “user equipment,” “mobile station,” “mobile,” “mobile device,” “subscriber station,” “subscriber equipment,” “access terminal,” “terminal,” “handset,” and similar terminology, refer to a wireless device utilized by a subscriber or user of a wireless communication service to receive or convey data, control, voice, video, sound, gaming, or substantially any data-stream or signaling-stream. The foregoing terms may be utilized interchangeably in the subject specification and related drawings. Likewise, the terms “access point,” “base station,” “base transceiver station”, “Node B.” “evolved Node B (eNode B),” home Node B (HNB),” “home access point (HAP),” or the like, may be utilized interchangeably in the subject specification and drawings, and refer to a wireless network component or apparatus that serves and receives data, control, voice, video, sound, gaming, or substantially any data-stream or signaling-stream from a set of subscriber stations.

As CMOS process scaling continues, digital components become cheaper, faster, and can consume less power. Therefore, increasing portions of radios that were once built from analog or radio frequency (RF) components can now be moved to the digital domain to reduce cost and power, and increase the flexibility of the solution with digital programmable elements. A digital transmitter comprises of digital signal processing (DSP) circuitry driving a high-speed digital-to-analog converter that outputs the desired RF waveform to a power amplifier (PA). The digital transmitter is reaching the crossover point such that it can supplant a conventional RF transmitter in mobile applications, particularly when fabricated using a semiconductor process with a feature size of 28 nm or smaller. Once the transmitter converts to a digital architecture, the digital signal processing creates new optimization opportunities that were not viable in a conventional analog transmitter.

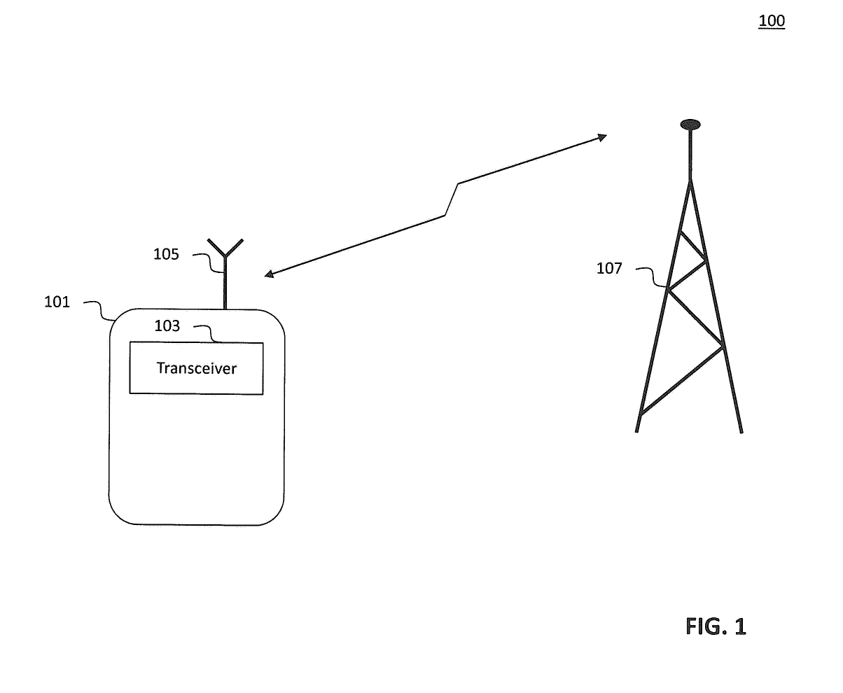

FIG. 1 illustrates a system 100, according to an embodiment of the present disclosure. For example, system 100 illustrates user equipment (UE) 101 that communicates with wireless network device 107 such as an evolved Node B (enode B), a base-station, or the like. In one example, UE 101 can be, but is not limited to, a mobile phone, tablet, laptop, wireless sensor, etc., and can include, but is not limited to, transceiver 103 (including a radio transmitter and receiver) and antenna 105, in addition to other modules, including one or more processors. According to one example, UE 101 is configured to use transceiver 103 and antenna 109 for communication with network device 111.

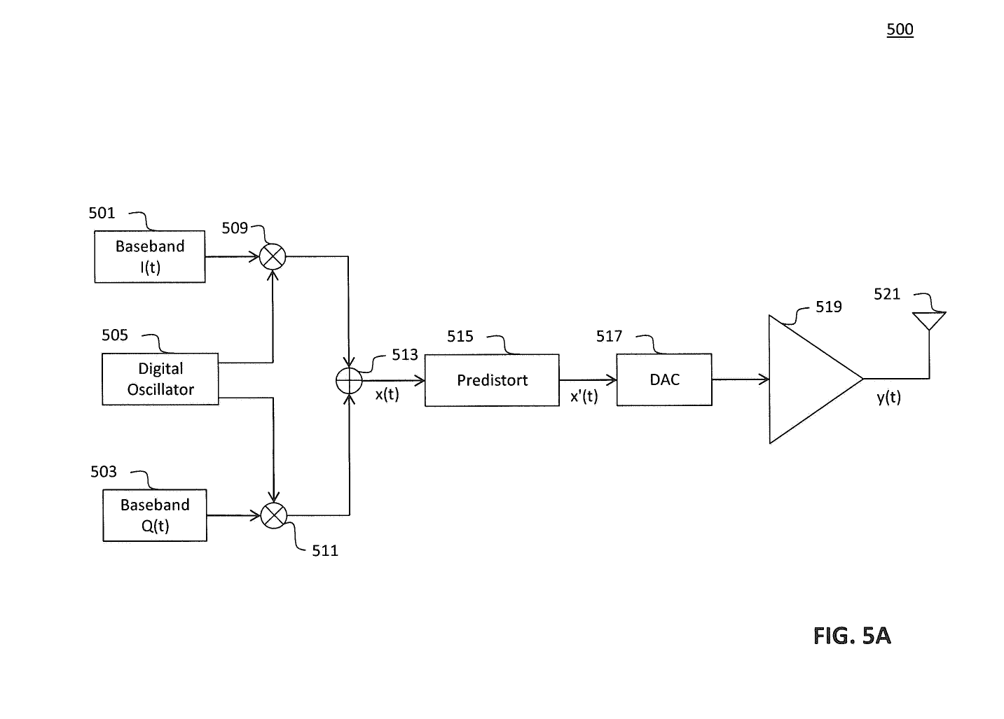

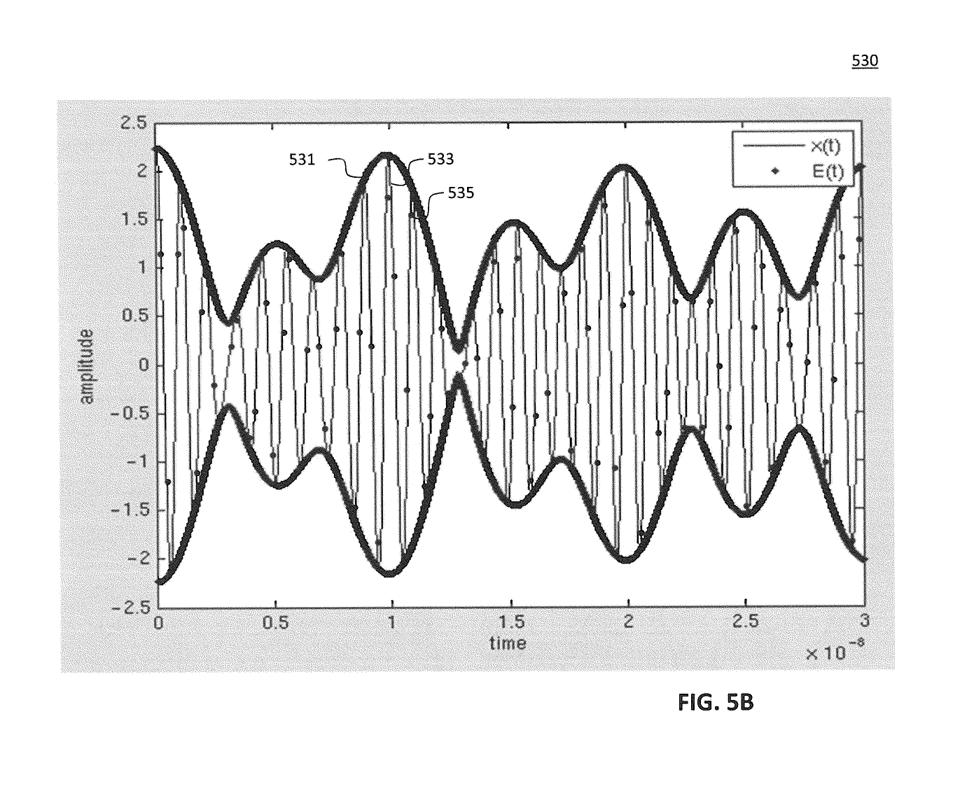

According to one example, transceiver 103 includes a digital transmitter that performs predistortion on the output waveform rather than on the envelope of the output waveform. As explained in more detail with respect to FIGS. 5A-5B, the predistortion compensation circuit is implemented after the RF carrier mixer (e.g. at the 5-10 Gsample/s rates) to correct the actual distortion from the power amplifier by analyzing the instantaneous amplitude of the RF signal. In addition, the predistorter can also impose a variable delay on the digital RF signals to model the amplitude-specific phase changes with the PA and downstream circuits. Therefore, it cancels the distortion of the power amplifier more effectively and allows the use of a lower power or cheaper power amplifier while still achieving sufficient performance. According to one example, the digital transmitter of transceiver 103 can reduce intermodulation products that would have been created with the power amplifier distortion, which can fall in-band with the transmit waveform.

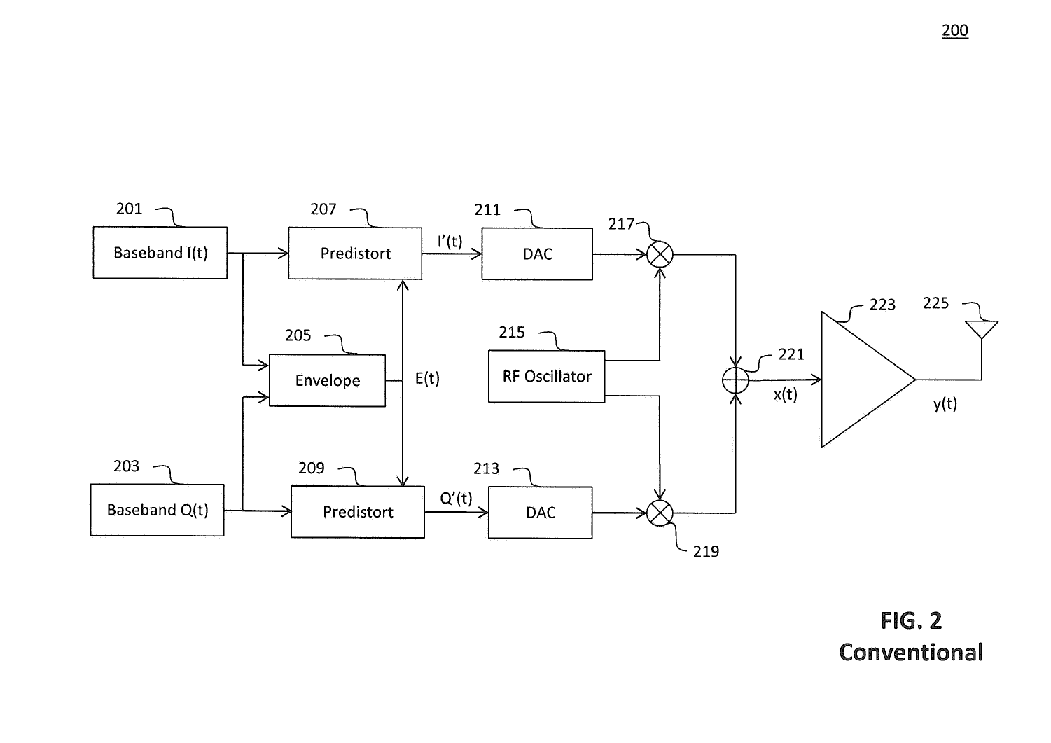

FIG. 2 illustrates a conventional transmitter where the predistortion is applied on the baseband signal based on the envelope of the signal. Transmitter 200 accepts a pair of digital baseband inputs, in-phase baseband I(t) 201 and quadrature phase baseband Q(t) 203. If no predistortion is applied, the baseband signals 201 and 203 (e.g., low frequency signals) are converted to analog waveforms using digital to analog converters (DAC) 211 and 213. Oscillator 215 generates cosine and sine waves at the carrier frequency f_{c}, and the analog baseband waveforms are mixed (multiplied) with the carrier waveforms using mixers 217 and 219 and are further summed using adder 221 to generate the transmit signal x(t).

x(t)=I(t)cos(2πf_{c}t)+Q(t)sin(2πf_{c}t)

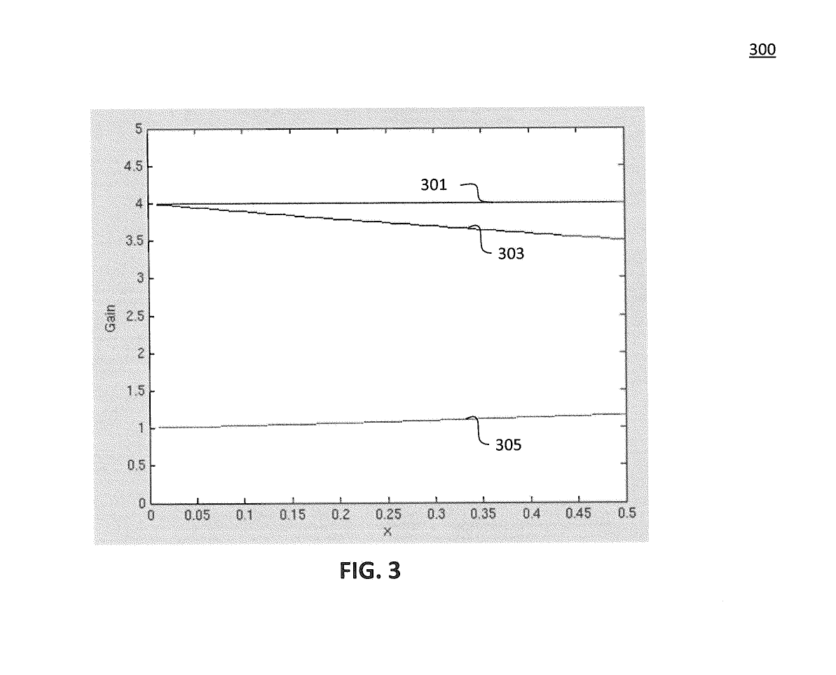

Power amplifier 223 can be used to amplify transmit signal x(t) to desired power level (y(t)=Ax(t)) and to drive antenna 225. An ideal power amplifier would produce an output signal that is directly proportional to the input signal (e.g., with a constant gain.) However, real power amplifiers begin to saturate as the amplitude of the input signal increases, resulting in a smaller-than-desired gain for higher values of the amplitude of the input signal. This behavior of power amplifiers is shown in FIG. 3. The x axis of FIG. 3 represents amplitude of an input signal to the power amplifier (such as x(t) to power amplifier 223) and y axis of FIG. 3 represents the gain of the amplifier. Graph 301 shows an ideal gain of the amplifier, which is constant irrespective of the amplitude of the input signal. However, graph 303 represents the real gain of the amplifier that decreases as the amplitude of the input signal increases. This may be referred to as saturation, and creates additional and unwanted signal components that are known general as signal distortion or harmonics.

Referring back to FIG. 2, conventional transmitters compensate for the distortion by anticipating it and adjusting baseband inputs 201 and 203, accordingly. Baseband input signal I(t) 201 passes through predistort module 207. Baseband input signal Q(t) 203 passes through predistort module 209. Predistort modules 207 and 209 have a gain that increases with the amplitude of the baseband signals, as illustrated by graph 305 of FIG. 3. The increase in the gain of predistort modules 207 and 209 is to compensate for the distortion produced by power amplifier 223. The product of the predistortion and distortion transfer functions is preferably the ideal constant gain.

Predistortion operates on the baseband signals 201 and 203. Because power might be carried in baseband signal 201 and/or 203, predistortion gain depends on the envelope of the baseband signal.

E(t)=\sqrt{I²(t)+Q²(t)}

Envelope module 205 calculates envelope E(t) and sends the calculated envelope to predistort modules 207 and 209, which determine the appropriate predistortion gain(s) for the baseband signals 201 and 203 and scales these signals accordingly to produce predistorted signals I′(t) and Q′(t).

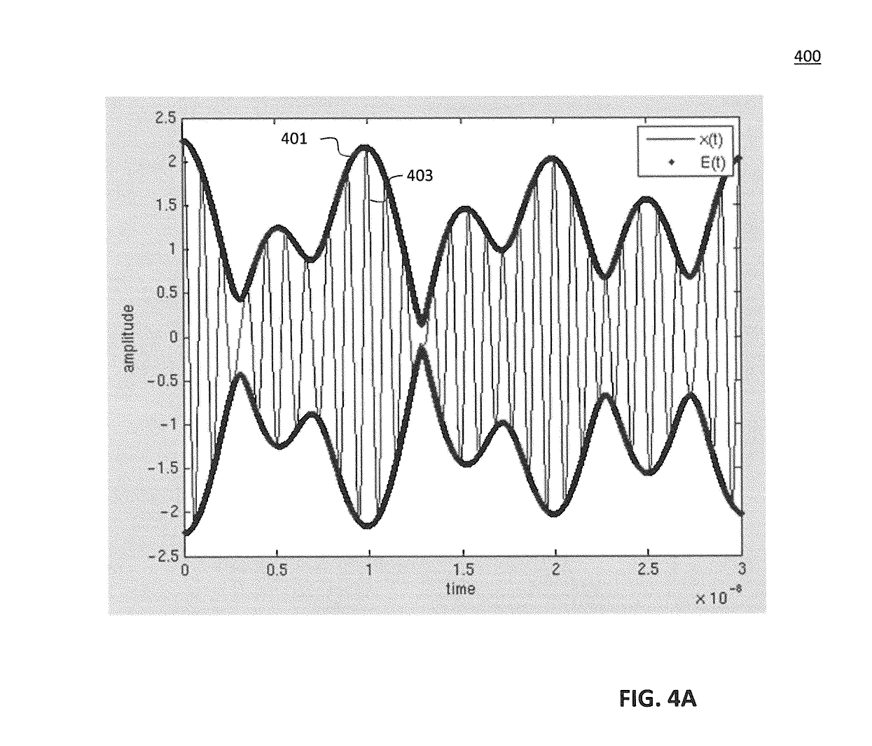

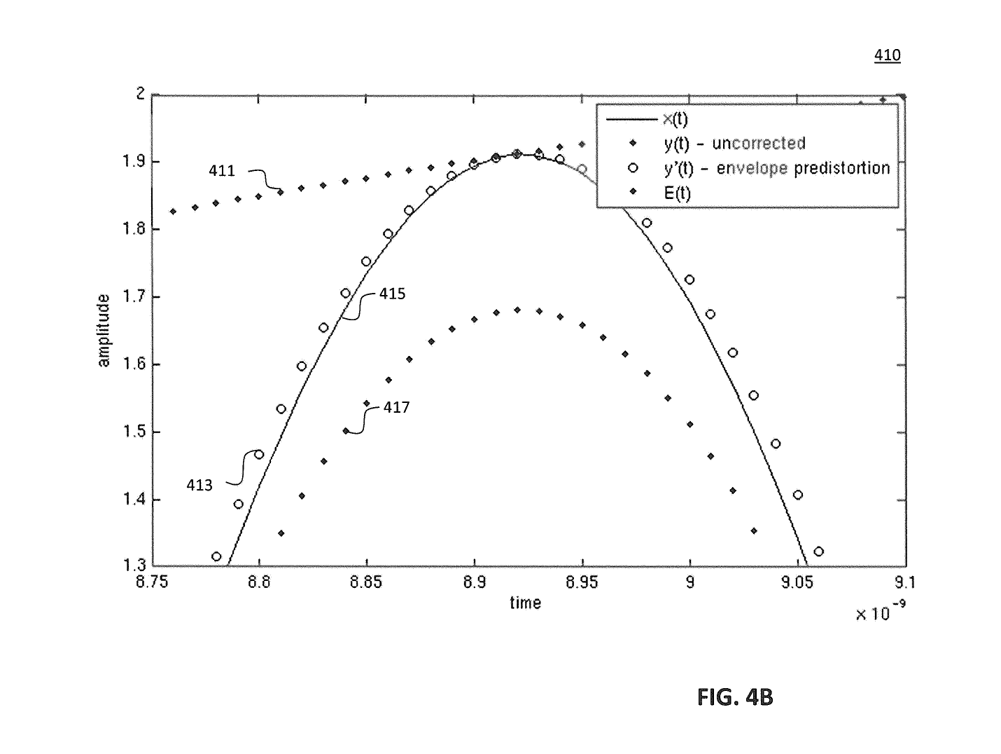

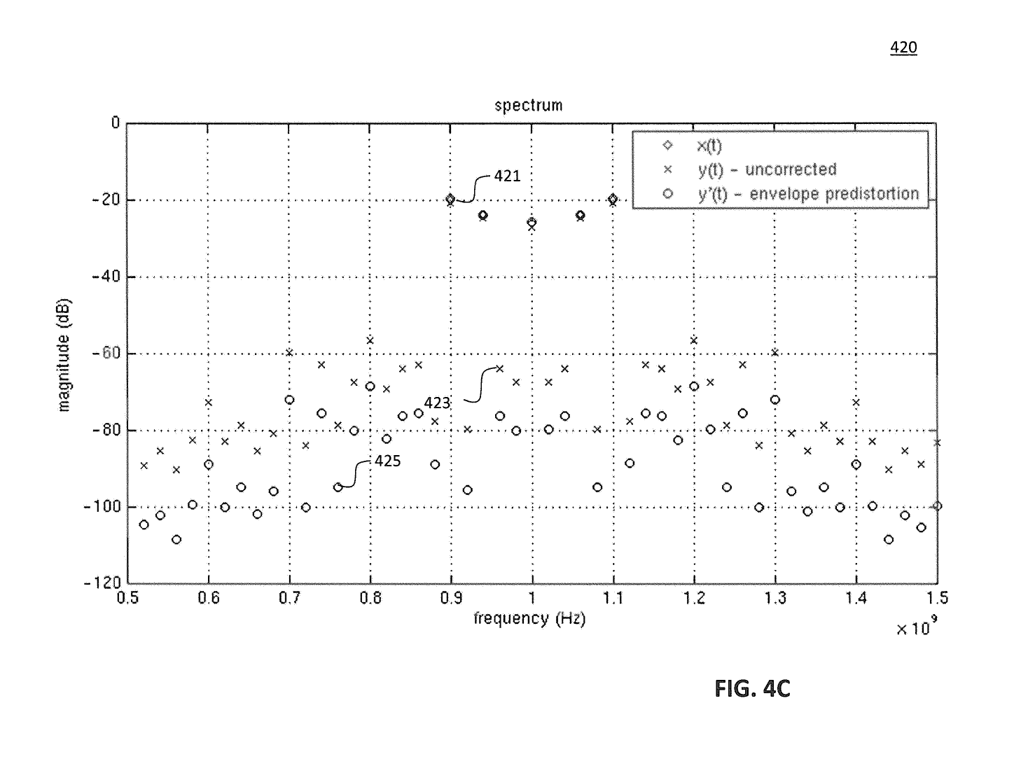

FIG. 4A illustrates an ideal transmit signal x(t) 403 oscillating at the carrier frequency within the envelope E(t) 401, according to one example. FIG. 4B illustrates a zoom on part of one cycle of the carrier, where 411 represents envelope E(t) and 415 illustrates transmit signal x(t). In addition to the envelope and the transmit signal, FIG. 4B illustrates distorted and uncorrected output y(t) at 417 taken at the output of power amplifier 223, which is lower than intended. When predistortion is applied based on the envelope, the corrected output y′(t) is shown with circles 413. At its maximum value, the corrected output 413 substantially matches the desired x(t) 415, as can be seen where the circles 413 fall on the line 415. But at intermediate values, the corrected output 413 is slightly larger than desired because the predistortion is based on the envelope rather than the actual signal and hence is somewhat too large. This conventional form of predistortion is called envelope predistortion.

FIG. 4C illustrates the impact of distortion and envelope predistortion in the frequency domain, according to one example. The transmit signal x(t), which is presented by diamonds 421, has −20 to −25 dB of energy at five frequencies centered around 1 GHz. When distortion is introduced, y(t), which is presented by crosses 423, has energy as great as −57 dB at intermodulation product frequencies. These undesired products can interfere with the signal being received, or other sensitive signals. When envelope predistortion is applied, y′(t), presented by circles 425, has intermodulation products driven down by about −13 dB to −70 dB and below. Hence, envelope predistortion reduces but does not eliminate the intermodulation products.

In a practical system, the intermodulation products must be small enough to avoid interfering with a weak signal that is being received at a receiver. Thus, the power amplifier in the transmitter is usually operated at a high bias point with minimal distortion so that envelope predistortion is sufficient to reduce the intermodulation products below an acceptable threshold. If a more accurate predistortion method existed, the power amplifier could operate at a lower bias point and save considerable power. Alternatively, the existing power amplifier could target applications that require even lower distortion.

FIG. 5A illustrates a digital transmitter with sample rate digital predistortion, according to one embodiment of the disclosure. According to this exemplary embodiment, predistortion occurs after the baseband signal has been mixed with the carrier frequency so that the predistortion is performed on the up-converted signal. According to this example, baseband signals 501 and 503 are mixed with the carrier frequency generated by digital oscillator 505 using mixers 509 and 511 and adder 513. According to one example, oscillator 505 and mixers 509 and 511 are constructed using digital circuits and digital to analog converter 517 is after the mixers 509 and 511 and after predistort module 515.

Although FIG. 5A illustrates a digital RF signal x(t) generated based on baseband signals and a carrier signal, this disclosure is not limited to this example and any digital RF signal generator, which can generate high speed digital signals, can be used. Predistortion module 515 (e.g., a sample rate predistorter) is configured to predistort the digital RF signal x(t) so as to compensate for distortion associated with transmitter 500 that is generated subsequent to an output of predistortion module 515 (for example, generated at power amplifier 519.) Predistortion module 515 is configured to generate digital predistorted signal x′(t) based on input signal x(t).

According to one example, digital RF signal x(t) can include a plurality of samples that define a modulated carrier having a frequency that exceed a bandwidth of the baseband digital signals 501 and 503. According to this example, predistortion module 515 can perform the compensation on at least a subset of the plurality of samples of the digital RF signal. Alternatively or additionally, transformation of baseband digital signals 501 and 503 to digital RF signal x(t) can include upsampling and translation of baseband signals 501 and 503 to generate the digital RF signal. In another example, transformation of baseband digital signals 501 and 503 to digital RF signal x(t) can include upsampling and digital modulation of baseband signals 501 and 503 to generate digital RF signal.

According to one example, the predistortion gain of predistortion module 515 can be determined based on a priori testing of power amplifier 519 to determine the gain of the amplifier with varying amounts of distortion. In other words, the power amplifier 519 is pre-characterized to determine the amount of gain compression for varying input signal levels. Accordingly, the pre-distortion module 515 can then implement the predistortion gain based on a given RF signal amplitude to as to counter any distortion that will be caused by the power amplifier 519 for the given RF signal amplitude. The predistortion module can also apply variable amounts of delay on the digital signal based on the signal amplitude to compensate for the amplitude-based delay characteristics of the PA. There are common digital resampling techniques like the Farrow filter that can apply fine-grain delay into a signals. In one example, predistortion module 515 is configured to perform time-dependent predistortion. Digital to analog converter 517 is configured to convert digital predistorted signal x′(t) to an analog predistorted signal, which will be amplified using power amplifier 519 and will be transmitted using antenna 521. According to one example, digital to analog converter 517 operates at full sample rate (typically 4-10 times the carrier frequency), so it might be more complex and may need more power than a conventional configuration. However, costly analog RF oscillator and mixer in conventional transmitters are replaced with smaller and lower-power digital circuits.

According to one example, predistortion module 515 is configured to perform predistortion on the digital RF signal at a sample rate associated with digital to analog converter 517. As discussed above, this full sample rate can be 4-10 times the carrier frequency. Further, the predistortion is performed on each sample of the input waveform, instead of the waveform envelope as is conventionally done. For example, FIG. 5B illustrates a transmit signal x(t) 533 oscillating at the carrier frequency within the envelope E(t) 531, where the predistortion circuitry operates at the full sample rate based on samples 535 that form the transmit signal 533. According to this example, instead of using envelope 531 for predistortion (as in a conventional transmitter), samples 535 of digital RF signal x(t) 533 are used by predistortion module 515 to predistort the digital RF signal x(t), so as to compensate for distortion associated with transmitter 500 that is generated subsequent to an output of predistortion module 515. In another embodiment, the predistortion module 515 can perform predistortion at a sample rate different than the sample rate of digital to analog converter 517.

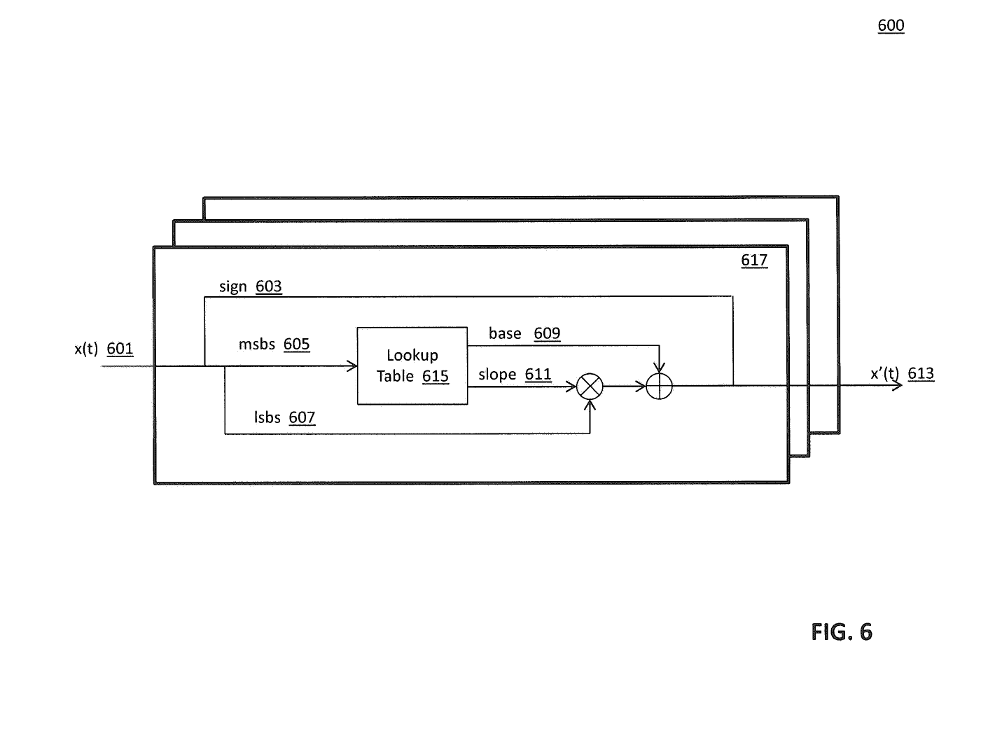

FIG. 6 illustrates an implementation of a predistortion module, according to an exemplary embodiment. Predistortion module 600 (which can be used as predistortion module 515 of FIG. 5A) can deliver very high data rates to digital to analog converter 517. Therefore, according to one example, predistortion module 600 can be divided into many channels for lanes 617 (e.g., 8, 12, or 16 in 28 nm CMOS), each running in parallel at a fraction of the sample rate. The samples can be de-multiplexed, processed in parallel individuals channels, and be re-multiplexed back together to a serial data stream. According to one example, the predistortion module can compute a piecewise linear approximation to the predistortion curve using a lookup table and a multiply-accumulator. In this way, a small table consuming low power can be used. Using a piecewise linear approximation is an exemplary implementation. Other methods for approximating the predistortion gain can also be used.

Input signal x(t) 601 arrives at predistortion module 600 in sign-magnitude form. Predistortion is computed on the magnitude of signal x(t), based on the pre-characterization of the power amplifier 519, or other distortion producing element. The most significant bits (msbs) 605 of the input signal x(t) 601 are used to index a lookup table 615, which returns a base value 609 and a slope value 611. Slope value 611 is multiplied by the least significant bits (lsbs) 607 of the input signal x(t) 601, and is added to base value 609 to produce the predistorted magnitude. This is combined with the original sign bit to produce output signal x′(t) 613, which is a digital predistorted signal.

In one exemplary implementation that can be used for communication systems such as 3G/LTE/WiFi, the sample rate is 10 GHz and the carrier is between 0.7 and 2.5 GHz. The transmit signal x(t) is represented with 1 sign bit, 1 integer bit, and 12 fractional bits. The digital circuitry including the predistortion module 600 operates with 16 channels, each running at 625 MHz. The lookup table contains 32 entries and is indexed by the integer bit and 4 most significant fractional bits of x(t), while the other 8 least significant bits drive the multiplier. According to this example, predistortion gain 305 of FIG. 3 is divided into 32 points, the values of which are stored in the lookup table. As discussed above, the predistortion gain is that needed to add to the signal to offset the gain compression illustrated by 303 that is caused by power amplifier distortion. When a sample of signal x(t) 601 is received, the integer bit and 4 most significant fractional bits of this sample are used to look up the table 615 and determine base 609 and slope 611. In one example, the determined slope 611 can be the slope of predistortion gain 305 of FIG. 3 at base 609 according to a linear approximation. Next, the determined slope 611 is multiplied by the 8 least significant bits of signal x(t) 601 and the result is added to the determined base 609. This new value (also considering the sign of signal x(t)) is the predistorted signal x′(t). In this way the sample of signal x(t) 601 is predistorted using predistortion gain 305 of FIG. 3 to generate predistorted sample x′(t) using a lookup table with a small number of entries. In this example, the small size of the lookup table helps save energy when the calculations are performed at high sample rates. In another exemplary implementation, the predistortion circuitry also considers the history of previous samples to perform time-dependent predistortion.

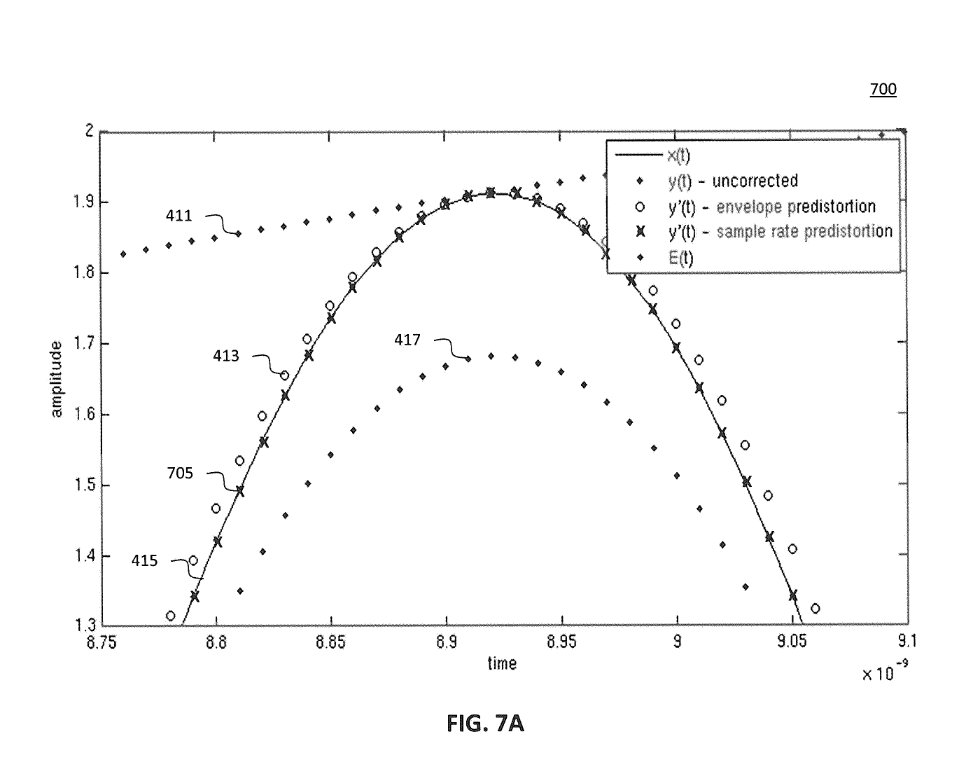

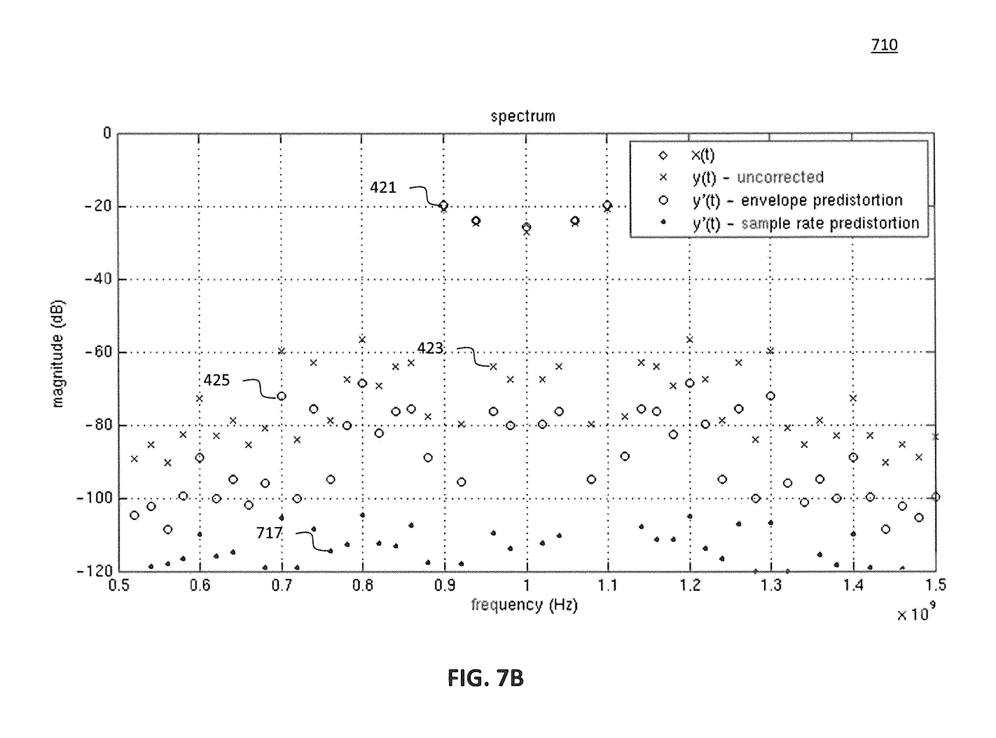

FIG. 7A illustrates the benefit of using predistort module 515 (e.g., sample rate predistortion) in the architecture illustrated in FIG. 5, according to one example. In one example, the predistortion can now correct every sample, so the output matches the desired transmit signal at substantially every point, not just at the top of the envelope. FIG. 7A includes the results of predistortion using transmitter 500 of FIG. 5, and further includes the results illustrated in FIG. 4B for comparison. Diamonds 411 represents envelope E(t) and line 415 illustrates transmit signal x(t). In addition to the envelope and the transmit signal, FIG. 7A illustrates distorted and uncorrected output y(t) at diamonds 417, which is lower than intended. When predistortion is applied based on the envelope (transmitter 200 of FIG. 2), the corrected output y′(t) is shown with circles 413. At its maximum value, the corrected output 413 matches the desired x(t) 415. But at intermediate values, the corrected output 413 is slightly larger than desired because the predistortion is based on the envelope rather than the actual signal and hence is somewhat too large at some portions of the signal. In contrast, when sample rate predistortion is applied using transmitter 500 of FIG. 5, the corrected output is shown with crosses (x) 705, which more closely match the desired x(t) 415.

FIG. 7B illustrates the benefit of sample rate predistortion in the frequency domain, according to one example. FIG. 7B can be compared to FIG. 4C, which illustrates conventional predistortion results in frequency domain. In this example, the intermodulation products, shown as dots 717, are now pushed below −105 dB, a 35 dB improvement over envelope predistortion. In practice, the effectiveness of the sample rate predistortion is limited primarily by the accuracy of the a priori characterization of the distortion produced by the offending device (e.g. power amplifier 519). By using the sample rate pre-distortion provided herein, more distortion can be tolerated because it is corrected. Accordingly, the bias point of the power amplifier can be lowered, which consumes less power. This is beneficial in advanced technologies where the cost and power of the digital hardware is lower than that of the RF components.

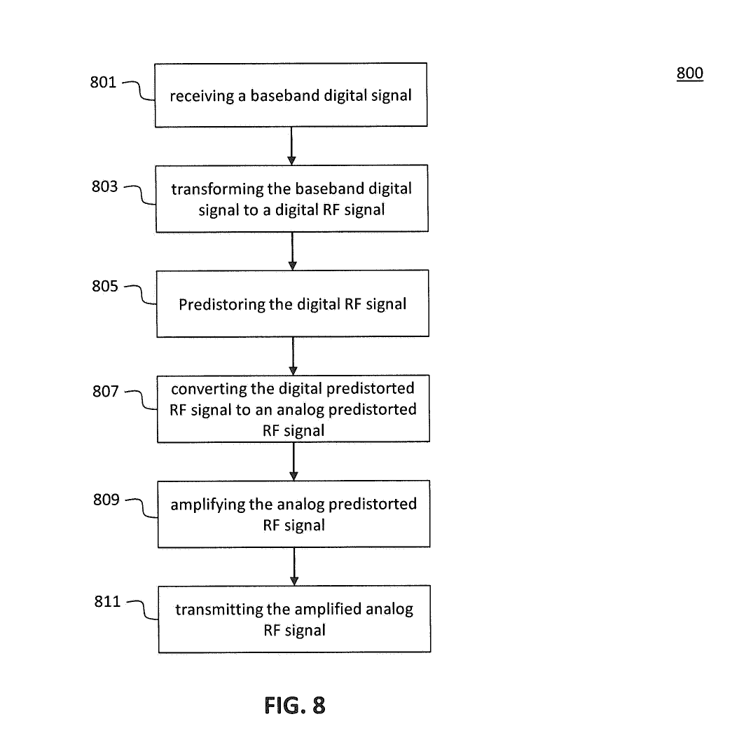

FIG. 8 is a flowchart depicting a method 800, according to an embodiment of the present disclosure. For example, method 800 can be performed by transmitter 500. It is to be appreciated not all steps may be needed to perform the disclosure provided herein. Further, some of the steps may be performed simultaneously, or in a different order than that shown in FIG. 8, as will be understood by those skilled in the art. Reference is made to transmitter 500 in FIG. 5 merely for convenience of discussion. Other systems may be used to perform the method as will be understood by those skilled in the arts.

In step 801, a baseband digital signal is received. In one example, a digital RF signal generator (such as, for example, digital oscillator 505, mixers 509 and 511, and adder 513) is configured to receive the RF signal. In step 803, the baseband digital signal is transformed to a digital RF signal. For example, the digital RF signal generator is configured to up-convert the baseband signal to the RF signal. According to one example, the digital RF signal includes a plurality of samples that define a modulated carrier having frequency that exceeds a bandwidth of the baseband digital signal. In one example, transforming the baseband digital signal can include upsampling and digital frequency translation of the baseband digital signal to generate the digital RF signal. Additionally or alternatively, transforming the baseband digital signal includes upsampling and digital modulation of the baseband digital signal to generate the digital RF signal.

In step 805, the digital RF signal is predistorted, generating a digital predistorted RF signal. According to one example, predistortion module 517 of FIG. 5 is used to predistort the digital RF signal. The digital RF signal is predistorted so as to compensate for distortion that is generated subsequent to the predistorting. According to one example, predistorting includes performing the predistortion on at least a subset of the plurality of samples of the digital RF signal. In one example, predistorting step 805 can include predistorting the digital RF signal at a sample rate associated with that of digital to analog converter 517. Alternatively, the predistorting step 805 can include predistorting the digital RF signal at a sample rate that is different than that of digital to analog converter 517.

According to one embodiment, predistorting step 805 can include using a lookup table to determine, based on most significant bits of the digital RF signal, a base value and a slope value of a compensation gain necessary to correct the distortion. Step 805 can further include multiplying the slope value by the least significant bits of the digital RF signal and adding the base value from the table to generate a magnitude of the digital predistorted RF signal, and using the magnitude of the digital predistorted RF signal and a sign of the digital RF signal to generate the digital predistorted RF signal.

In step 807, the digital predistorted RF signal is converted to an analog predistorted RF signal. And in step 809, the analog predistorted RF signal is amplified by the power amplifier 519 that causes the distortion that has been pre-compensated. In step 811, the amplified analog RF signal is transmitted.

The predistortion has been described herein as being applied at radio frequency (RF) including (Hz frequency ranges, in contrast to baseband frequencies. However, the disclosure is not limited to RF, as the disclosure contemplates that the predistortion may also be applied at higher or lower frequencies relative RF that are still above baseband.

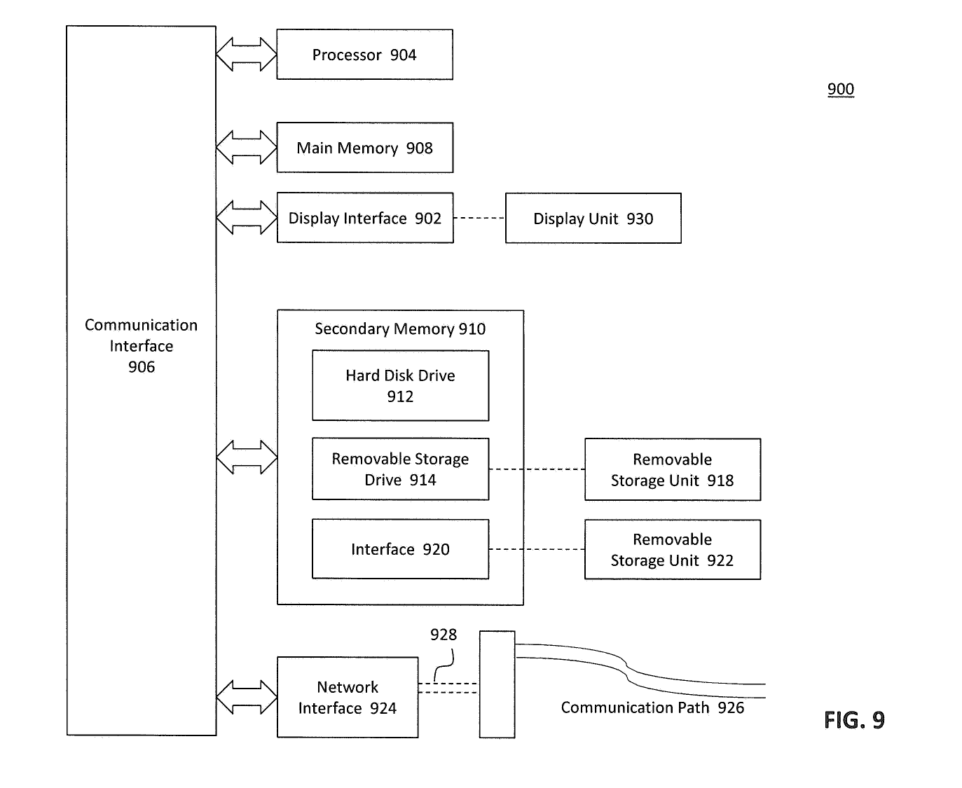

Various aspects of the present disclosure can be implemented by software, firmware, hardware, or a combination thereof FIG. 9 illustrates an example computer system 900 in which the present disclosure, or portions thereof, can be implemented as computer-readable code. For example, method 800 can be implemented by computer system 900. Various embodiments of the disclosure are described in terms of this example computer system 900. After reading this description, it will become apparent to a person skilled in the relevant art how to implement the disclosure using other computer systems and/or computer architectures.

Computer system 900 includes one or more processors, such as processor 904. Processor 904 can be a special purpose or a general purpose processor. Processor 904 is connected to a communication infrastructure 906 (for example, a bus or network).

Computer system 900 also includes a main memory 908, preferably random access memory (RAM), and may also include a secondary memory 910. Secondary memory 910 may include, for example, a hard disk drive 912, a removable storage drive 914, and/or a memory stick. Removable storage drive 914 may comprise a floppy disk drive, a magnetic tape drive, an optical disk drive, a flash memory, or the like. The removable storage drive 914 reads from and/or writes to a removable storage unit 918 in a well-known manner. Removable storage unit 918 may comprise a floppy disk, magnetic tape, optical disk, etc. that is read by and written to by removable storage drive 914. As will be appreciated by persons skilled in the relevant art(s), removable storage unit 918 includes a computer usable storage medium having stored therein computer software and/or data.

In alternative implementations, secondary memory 910 may include other similar means for allowing computer programs or other instructions to be loaded into computer system 900. Such means may include, for example, a removable storage unit 922 and an interface 920. Examples of such means may include a program cartridge and cartridge interface (such as that found in video game devices), a removable memory chip (such as an EPROM, or PROM) and associated socket, and other removable storage units 922 and interfaces 920 that allow software and data to be transferred from the removable storage unit 922 to computer system 900.

Computer system 900 may also include a communications interface 924. Communications interface 924 allows software and data to be transferred between computer system 900 and external devices. Communications interface 924 may include a modem, a network interface (such as an Ethernet card), a communications port, a PCMCIA slot and card, or the like. Software and data transferred via communications interface 924 are in the form of signals that may be electronic, electromagnetic, optical, or other signals capable of being received by communications interface 924. These signals are provided to communications interface 924 via a communications path 926. Communications path 926 carries signals and may be implemented using wire or cable, fiber optics, a phone line, a cellular phone link, an RF link or other communications channels.

In this document, the terms “computer program medium” and “computer usable medium” are used to generally refer to media such as removable storage unit 918, removable storage unit 922, and a hard disk installed in hard disk drive 912. Signals carried over communications path 926 can also embody the logic described herein. Computer program medium and computer usable medium can also refer to memories, such as main memory 908 and secondary memory 910, which can be memory semiconductors (e.g. DRAMs, etc.). These computer program products are means for providing software to computer system 900.

Computer programs (also called computer control logic) are stored in main memory 908 and/or secondary memory 910. Computer programs may also be received via communications interface 924. Such computer programs, when executed, enable computer system 900 to implement the present disclosure as discussed herein. In particular, the computer programs, when executed, enable processor 904 to implement the processes of the present disclosure. Accordingly, such computer programs represent controllers of the computer system 900. Where the disclosure is implemented using software, the software may be stored in a computer program product and loaded into computer system 900 using removable storage drive 914, interface 920, hard drive 912 or communications interface 924.

The disclosure is also directed to computer program products comprising software stored on any computer useable medium. Such software, when executed in one or more data processing device, causes a data processing device(s) to operate as described herein. Embodiments of the disclosure employ any computer useable or readable medium, known now or in the future. Examples of computer useable mediums include, but are not limited to, primary storage devices (e.g., any type of random access memory), secondary storage devices (e.g., hard drives, floppy disks, CD ROMS, ZIP disks, tapes, magnetic storage devices, optical storage devices, MEMS, nanotechnological storage device, etc.), and communication mediums (e.g., wired and wireless communications networks, local area networks, wide area networks, intranets, etc.).

The exemplary embodiments described herein are provided for illustrative purposes, and are not limiting. Other exemplary embodiments are possible, and modifications may be made to the exemplary embodiments within the spirit and scope of the disclosure.

It is to be appreciated that the Detailed Description section, and not the Abstract section, is intended to be used to interpret the claims. The Abstract section may set forth one or more, but not all exemplary embodiments, of the disclosure, and thus, are not intended to limit the disclosure and the appended claims in any way.

The disclosure has been described above with the aid of functional building blocks illustrating the implementation of specified functions and relationships thereof. The boundaries of these functional building blocks have been arbitrarily defined herein for the convenience of the description. Alternate boundaries may be defined so long as the specified functions and relationships thereof are appropriately performed.

It will be apparent to those skilled in the relevant art(s) that various changes in form and detail can be made therein without departing from the spirit and scope of the disclosure. Thus the disclosure should not be limited by any of the above-described exemplary embodiments. Further, the claims should be defined only in accordance with the following claims and their equivalents.

What is claimed is:

1. A transmitter, comprising:
a digital radio frequency (RF) signal generator configured to receive a baseband digital signal and transform the baseband digital signal to a digital RE signal;
a sample rate predistorter configured to predistort the digital RF signal so as to compensate for distortion associated with the transmitter that is generated subsequent to an output of the sample rate predistorter, and resulting in a digital predistorted RE signal; and
a digital to analog converter (DAC) configured to convert the digital predistorted RE signal to analog, resulting in an analog predistorted RF signal.

2. The transmitter of claim 1, wherein:
the digital RE signal includes a plurality of samples that define a modulated carrier having frequency that exceeds a bandwidth of the baseband digital signal, and
the sample rate predistorter is configured to perform the predistortion on at least a subset of the plurality of samples of the digital RF signal.

3. The transmitter of claim 1, wherein the transformation of the baseband digital signal includes upsampling and digital frequency translation of the baseband digital signal to generate the digital RF signal.

4. The transmitter of claim 1, wherein the transformation of the baseband digital signal includes upsampling and digital modulation of the baseband digital signal to generate the digital RF signal.

5. The transmitter of claim 1, further comprising:
an amplifier configured to amplify the analog predistorted RE signal, the amplifier introducing at least some of the distortion.

6. The transmitter of claim 1, wherein the distortion is non-linear.

7. The transmitter of claim 1, wherein the predistortion of the digital RF signal includes applying a digital delay to the digital RF signal.

8. The transmitter of claim 1, wherein the sample rate predistorter is configured to perform the predistortion on the digital RF signal at a sample rate associated with that of the DAC.

9. The transmitter of claim 1, wherein the sample rate predistorter is configured to perform the predistortion at a sample rate that is different than that of the DAC.

10. The transmitter of claim 1, wherein the sample rate predistorter includes a lookup table to determine, based on most significant bits of the digital RF signal, a base value and a slope value for generating the digital predistorted RF signal.

11. The transmitter of claim 10, wherein the sample rate predistorter is configured to multiply the slope value by the least significant bits of the digital RF signal and add the result of the multiplication to the base value to generate a magnitude of the digital predistorted RF signal.

12. A method, comprising:
receiving a baseband digital signal and transforming the baseband digital signal to a digital radio frequency (RF) signal;
predistorting the digital RF signal so as to compensate for distortion that is generated subsequent to the predistorting, and producing a digital predistorted RF signal; and
converting the digital predistorted RF signal to an analog predistorted RF signal.

13. The method of claim 12, wherein:
the digital RF signal includes a plurality of samples that define a modulated carrier having a frequency that exceeds a bandwidth of the baseband digital signal, and
the predistorting includes performing the predistortion on at least a subset of the plurality of samples of the digital RF signal.

14. The method of claim 12, wherein the transforming the baseband digital signal includes upsampling and digital frequency translation of the baseband digital signal to generate the digital RF signal.

15. The method of claim 12, wherein the transforming the baseband digital signal includes upsampling and digital modulation of the baseband digital signal to generate the digital RF signal.

16. The method of claim 12, further comprising:
amplifying the analog predistorted RF signal, wherein the amplifying introduces the distortion.

17. The method of claim 12, wherein the distortion is non-linear.

18. The method of claim 12, wherein the predistorting includes predistorting the digital RF signal at a sample rate associated with that of the DAC.

19. The method of claim 12, the predistorting includes predistorting the digital RF signal at a sample rate that is different than that of the DAC.

20. The method of claim 12, wherein the predistorting includes:
using a lookup table to determine, based on most significant bits of the digital RF signal, a base value and a slope value;
multiplying the slope value with the least significant bits of the digital RF signal and adding the result of the multiplication to the base value, to generate a magnitude of the digital predistorted RF signal; and
using the magnitude of the digital predistorted RF signal and a sign of the digital RF signal to generate the digital predistorted RF signal.
